(19) United States
(12) Patent Application Publication
(10) Pub. No.: US 2010/0119075 A1
(43) Pub. Date: May 13, 2010

(54) SPATIALLY ENVELOPING REVERBERATION IN SOUND FIXING, PROCESSING, AND ROOM-ACOUSTIC SIMULATIONS USING CODED SEQUENCES

(75) Inventors: Ning Xiang, Cohoes, NY (US); Eric A. Dieckman, Williamsburg, VA (US); Uday Trivedi, Chicago, IL (US)

Correspondence Address: RATNERPRESTIA, P.O. BOX 980, VALLEY FORGE, PA, 19482, US

(73) Assignee: Rensselaer Polytechnic Institute, Troy, NY (US)

(21) Appl. No.: 12/615,655

(22) Filed: Nov. 10, 2009

Related U.S. Application Data
(60) Provisional application No. 61/198,826, filed on Nov. 10, 2008.
(60) Provisional application No. 61/253,971, filed on Oct. 22, 2009.

(51) Int. Cl. H03G 3/00

(52) U.S. Cl. 381/63

(57) ABSTRACT

Methods and systems for simulating at least one room impulse response between two or more sound sources and two or more receivers positioned in an enclosure are provided. At least one early impulse response is generated that includes early reflections from the two or more sound sources to at least one of the receivers. At least one late impulse response is generated including a reverberation portion. The late impulse response is generated to spatially shape the reverberation portion corresponding to a spatial parameter of the enclosure. The at least one early impulse response is combined with the at least one late impulse response to form the at least one simulated room impulse response.

### CROSS REFERENCE TO RELATED APPLICATIONS

This application is related to and claims the benefit of U.S. Provisional Application No. 61/198,826 entitled SPATIALLY ENVELOPING REVERBERATION IN SOUND FIXING, PROCESSING, AND ROOM-ACOUSTIC SIMULATIONS USING CODED SEQUENCES filed on Nov. 10, 2008 and U.S. Provisional Application No. 61/253,971 entitled SPATIALLY ENVELOPING REVERBERATION IN SOUND FIXING, PROCESSING, AND ROOM-ACOUSTIC SIMULATIONS USING CODED SEQUENCES filed on Oct. 22, 2009, the contents of which are incorporated herein by reference.

### FIELD OF THE INVENTION

The present invention relates to the field of room impulse response simulation and, more particularly, to methods and systems for generating simulated room impulse responses including spatially enveloping reverberation.

### BACKGROUND OF THE INVENTION

Sound characteristics of an enclosure are generally due to a combination of direct sound received from a sound source, as well as indirectly received sound due to multiple reflections of the sound from the boundaries and other surfaces within the enclosure. In general, the transmitted sound may be reflected, absorbed and/or diffused by various surfaces within the enclosure prior to reaching the receiver. The absorption, reflectivity and diffusion characteristics of each surface may also vary as a function of frequency. The sound characteristics of an enclosure may be described with respect to a room impulse response (also referred to herein as an impulse response) between the sound source and the receiver.

Room impulse responses for an enclosure may also be used to determine various psychoacoustic parameters. The psychoacoustic parameters are related to acoustical attributes of an enclosure and are generally correlated with acoustical qualities of the enclosure. For example, the psychoacoustic parameters may be used to characterize an enclosure in terms of it's spaciousness, envelopment, clarity, reverberance and warmth of sound.

Room impulse responses may be measured or simulated. Room impulse responses, as well as psychoacoustic parameters, may be used to design acoustically desirable enclosures. Room impulse responses may also be combined with a desired sound signal, to create a virtual listening environment for the sound signal.

### SUMMARY OF THE INVENTION

The present invention is embodied in methods and systems for simulating at least one room impulse response between two or more sound sources and two or more receivers positioned in an enclosure. At least one early impulse response is generated that includes early reflections from the two or more sound sources to at least one of the receivers. At least one late impulse response is generated which includes a reverberation portion. The late impulse response is generated to spatially shape the reverberation portion corresponding to a spatial parameter of the enclosure. The at least one early impulse response is combined with the at least one late impulse response to form the at least one simulated room impulse response.

### BRIEF DESCRIPTION OF THE DRAWINGS

The invention may be understood from the following detailed description when read in connection with the accompanying drawings. It is emphasized that, according to common practice, various features/elements of the drawings may not be drawn to scale. On the contrary, the dimensions of the various features/elements may be arbitrarily expanded or reduced for clarity. Moreover, in the drawings, common numerical references are used to represent like features/elements. Included in the drawing are the following figures:

FIG. 1 is a overhead view diagram of an enclosure illustrating impulse responses between multiple sources and multiple receivers;

FIG. 2 a functional block diagram illustrating an exemplary system for simulating room impulse responses of an enclosure, according to an embodiment of the present invention;

FIG. 3A is graph illustrating portions of a simulated room impulse response generated by components of the exemplary system shown in FIG. 2;

FIG. 3B is graph of an example room impulse response generated by the exemplary system shown in FIG. 2;

FIG. 4A is a functional block diagram illustrating an exemplary late impulse response (IR) generator, according to an embodiment of the present invention;

FIG. 4B is a functional block diagram illustrating an exemplary late IR generator, according to another embodiment of the present invention;

FIG. 5 is a functional block diagram illustrating an exemplary spatial shaping generator, according to an embodiment of the present invention;

FIG. 6 is a graph of spaciousness for various attenuation parameter values used in the spatial shaping generator shown in FIG. 5, illustrating the capability of the spatial shaping generator to generate spatially enveloping reverberation;

FIG. 7 is a graph of a spatial index for a predetermined concert hall as a function of frequency and a spatial index for a late impulse response simulated by the exemplary late IR generator shown in FIG. 4B, illustrating the capability of the late IR generator to generate spatially enveloping reverberation which corresponds with an actual enclosure;

FIGS. 8A, 8B, 8C and 8D are graphs illustrating an example of attenuation coefficient selection as a function of channel for an exemplary late IR generator shown in FIG. 4B configured for eight channels;

FIGS. 9A, 9B, 9C and 9D are graphs illustrating another example of attenuation coefficient selection as a function of channel for an exemplary late IR generator shown in FIG. 4B configured for eight channels;

FIG. 10 is a graph of 1-IACC (interaural cross correlation coefficient) as a function of frequency used in the exemplary spatial-index shaping applicator shown in FIG. 4B, according to an embodiment of the present invention;

FIG. 11 is a flowchart illustrating an exemplary method for generating simulated room impulse responses, according to an embodiment of the present invention;

FIG. 12A is a flowchart illustrating an exemplary method for generating late impulse responses, according to an embodiment of the present invention;

FIG. 12B is a flowchart illustrating an exemplary method for generating late impulse responses, according to an other embodiment of the present invention;

FIGS. 13A, 13B and 13C are graphs of spatial index as a function of frequency for several example profiles used to test simulated impulse responses; and

FIGS. 14A, 14B and 14C are graphs of psychological spatial index as a function of physical spatial index illustrating results of testing for the profiles shown in respective FIGS. 13A, 13B and 13C.

### DETAILED DESCRIPTION OF THE INVENTION

In conventional room impulse response simulation, including simulation of binaural room impulse responses, there may be a substantial computational load to simulate a full scope of the room impulse response. To reduce the computational load, conventional simulators often simulate an early part of the room reflections, while appending an artificially produced late part (typically referred to as the reverberation tail) to the binaural simulation of the early part of the room impulse response.

Conventional room impulse response simulators, however, do not take into account the psychoacoustic qualities of the enclosure when generating the reverberation tail. For example, one acoustical quality of an enclosure is its perceived spaciousness. In general, spaciousness includes an apparent source width (ASW) of the early part of the room impulse response and a listener envelopment (LEV) of the reverberant tail. Both the ASW and the LEV may be determined for enclosures from the interaural cross correlation coefficient (IACC). The IACC is a measure of the difference in sounds arriving at each of the ears at any instant in time. For example, a sound wave that arrives laterally to a listener may be received by one ear earlier than the other, and the character of the sound may be different (due to the intervening head). Accordingly, the IACC may provide a measure of spatial impression of the enclosure. Typically a measure of the IACC from the direct sound to about 80 msec is used to determine the ASW and a measure of the IACC after 80 msec is used to determine the LEV.

According to aspects of the present invention, the late impulse response is generated to include a perceived listener envelopment. The present invention uses deterministic coded signals to generate the late reverberation tail using a spatial shaping matrix. The spatial shaping matrix may be selected to provide a perceived spatially sounding enveloping reverberance. The reverberation tail may be appended to an early impulse response, which may also include a measure of perceived spaciousness. By including the spaciousness in the early part of the impulse response, as well as in the reverberation tail, the simulated room impulse response may have a more natural perceived spaciousness. The simulated room impulse responses may be used for filtering music and or speech signals. The signals may be rendered binaurally through headphones or transaural systems. The present invention may also be extended to multiple channels of spatial reverberation. The present invention may be used for artificial reverberators, active field synthesizers, for producing digital sound and for audio mixing devices. The present invention may also be used in virtual reality systems.

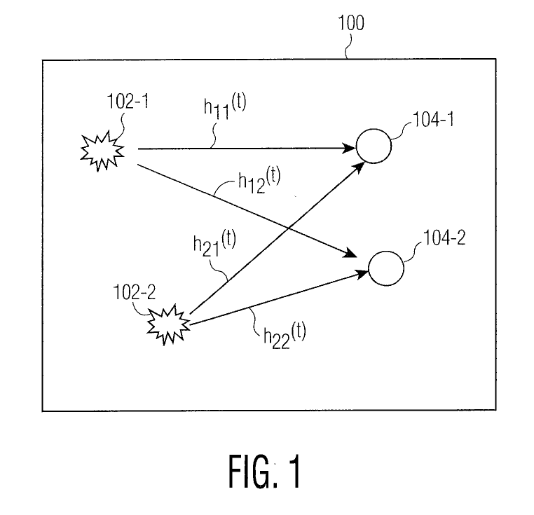

Referring to FIG. 1, an overhead view diagram of enclosure 100 is shown, illustrating impulse responses hᵢⱼ(t) between the ith sound source 102 and the jth receiver 104. Although FIG. 1 illustrates two sources 102-1, 102-2 and two receivers 104-1, 104-2, it is understood that enclosure 100 may include more than two sources 102 and/or more than two receivers 104. Accordingly, FIG. 1 generally relates to a scenario where there are multiple sound sources 102 and multiple receivers 104 capable of simultaneously receiving sound from the multiple sources 102.

As shown in FIG. 1, receiver 104-1 is associated with respective impulses responses h₁₁(t) (from source 102-1) and h₂₁(t) (from source 102-2). Similarly, receiver 104-2 is associated with respective impulse responses h₂₂(t) and h₁₂(t). In general, the jth receiver Yⱼ(t) receives:

$${Y}_{j} ( t ) = {\sum }_{i = 1}^{n} {X}_{i} ( t ) * {h}_{ij} ( t ) , i = 1 , … , n and j = 1 , … , p \qquad ( 1 )$$

where n represents the number of sources, p represents the number of receivers, X(t) represents the source signal for the ith source, t represents time and * represents the convolution operation. As can be seen by FIG. 1, the impulse responses hᵢⱼ(t) are a function of the locations of sources 102 and receivers 104 in enclosure 100.

Accordingly, all of the impulse responses between n sources 102 and p receivers 104 may be represented in vector form, h̅, as:

h̅=[h₁₁, . . . , hᵢⱼ . . . , hₙₚ]. (2)

In addition, the source signals may be represented in vector form as:

X̅=[X₁, . . . , Xₙ] (3)

and the received signals may be represented in vector form as:

Y̅=[Y₁, . . . , Yₚ] (4)

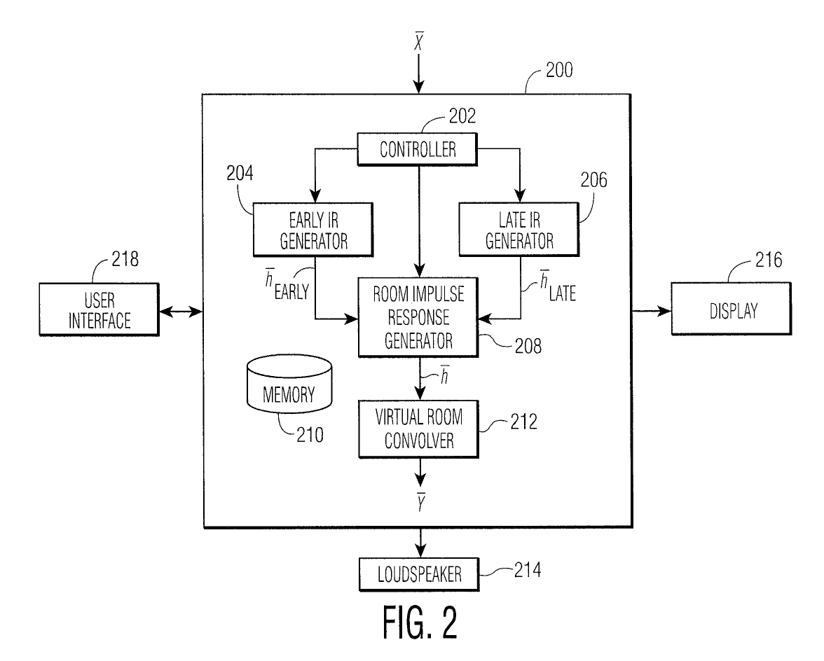

Referring next to FIG. 2, a functional block diagram of exemplary system 200 is shown for simulating room impulse responses from multiple sources and multiple receivers. Simulator 200 includes controller 202, early impulse response (IR) generator 204, late IR generator 206, room impulse response generator 208 and memory 210.

Memory 210 may store a plurality of predetermined enclosure parameters for use in generating the simulated room impulse response. For example, the predetermined enclosure parameters may include at least one of enclosure dimensions (e.g., length, width and height), acoustic properties (e.g., absorption characteristics or diffusion characteristics over a plurality of frequency bands for one or more surfaces of the enclosure) and psychoacoustic properties (e.g., an interaural cross correlation (IACC)) for a plurality of predetermined enclosures. Memory 210 may also store one or more simulated room impulse responses, h̅. Memory 210 may further store one or more generated early impulse responses, h̅_{EARLY}, and/or late impulse responses, h̅_{LATE}. Memory 210 may be a magnetic disk, a database or essentially any local or remote device capable of storing data.

Controller 202 may be a conventional digital signal processor that controls generation of simulated room impulse responses in accordance with the subject invention. System 200 may include other electronic components and software suitable for performing at least part of the functions of generating the simulated room impulse response.

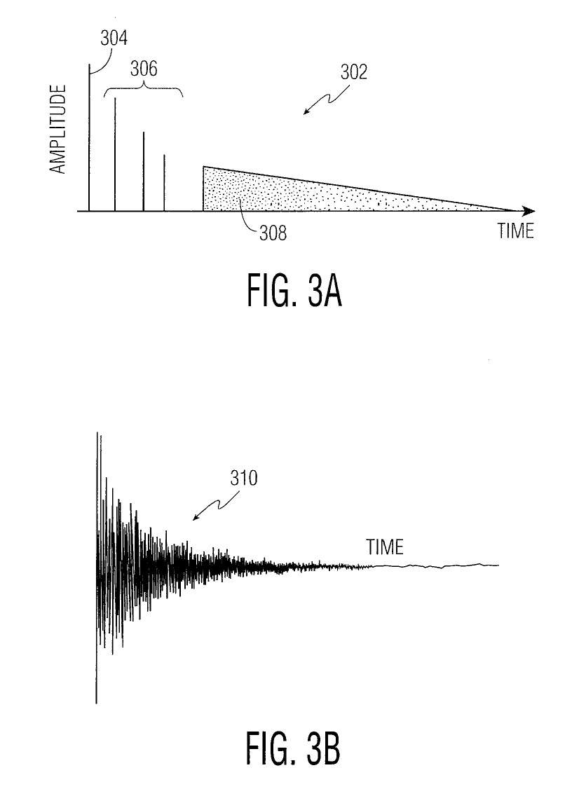

Referring to FIGS. 2, 3A and 3B, a description of generation of the early and late components of the impulse response, according to the present invention is described. In particular, FIG. 3A is a graph illustrating portions of simulated room impulse response 302 and; FIG. 3B is a graph of example simulated room impulse response 310 generated by system 200.

In general, room impulse response 302 is determined as a function of time. Room impulse response 302 includes direct sound component 304, early reflections 306 and reverberation tail 308. The early impulse response h̅_{EARLY} includes direct sound 304 and early reflections 306. The late impulse response h̅_{LATE} includes reverberation tail 308.

In FIG. 3A, direct sound 304 and early reflections 306 are illustrated as impulses associated with a respective time delay. The time delay corresponds to the length of each propagation path (divided by the speed of sound of the fluid in the enclosure) of respective direct sound 304 and reflections 306 to reach the receiver. In general, components of the early impulse response may be a function of the source and receiver locations. Although late impulse response 308 is shown as being a decaying solid region, the reverberation tail 308 includes a dense concentration of impulses.

Controller 202 may be configured to select predetermined enclosure parameters from memory 210 for generating a simulated room impulse response. Controller 202 may configure early IR generator 204 with the selected enclosure parameters retrieved from memory 210. Thus, early IR generator 204, as configured by the controller 202, may generate an early impulse response, h̅_{EARLY}.

Early IR generator 204 may generate the early impulse response based on the enclosure parameters (e.g., the enclosure dimensions and acoustical parameters of the enclosure) and the location of each source and each receiver in the room. According to the present invention, the early impulse response components 304 and 306 may be determined based on the propagation path lengths of the respective component in the enclosure from the source to the receiver. Early reflections 306 may include, for example, first and second order reflections of sound from surfaces of the enclosure. The time delay may be determined from the speed of sound of the fluid (e.g. 341 m/s for air under ambient conditions). For example, ray tracing techniques or image source modeling may be used to estimate the delay time and the amplitude of each reflection. Examples of simulating the early impulse response may be found, for example, in U.S. 2008/0273708 to Sandgren et al., entitled “Early Reflection Method for Enhanced Externalization,” the contents of which are incorporated herein by reference.

Controller 202 may also configure late IR generator 206 with the selected enclosure parameters retrieved from memory 210. Thus, late IR generator 206, as configured by the controller 202, may generate a late impulse response, h̅_{LATE}.

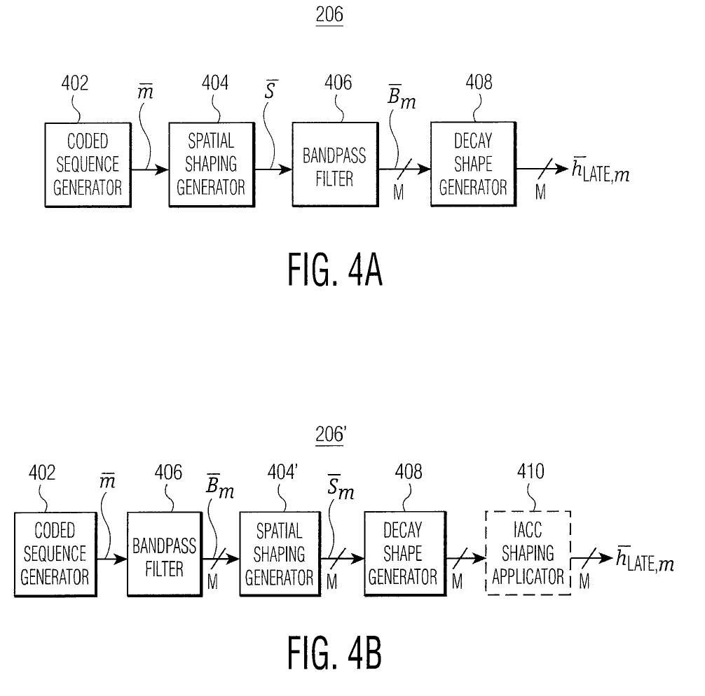

In conventional room impulse response simulators, reverberation tail 308 is typically simulated using statistical methods. For example, a pseudorandom sequence may be used with an exponential decay to simulate reverberation tail 308. The conventional methods, however, do not take into account the psychoacoustic properties of the enclosure, such as the spaciousness of the enclosure. According to an exemplary embodiment, late IR generator 206 incorporates a spatial shaping matrix to reverberation tail 308, based on the psychoacoustic parameters of the enclosure. Accordingly, any spatial envelopment present in the early impulse response may be matched by reverberant tail 306, thus, providing a more natural sounding listening experience. Late IR generator 206 is described further below with respect to FIGS. 4A and 4B.

Controller 202 may also configure room impulse response generator 208 to combine the early impulse responses h̅_{EARLY} and the late impulse responses h̅_{LATE} to form the simulated room impulse responses h̅.

Room impulse response generator 208 in general, may concatenate the early impulse responses generated by early IR generator 204 with the late impulse responses generated by late IR generator 206. For example, FIG. 3B illustrates simulated room impulse response 310 including an early impulse response concatenated at about 90 ms with a late impulse response.

According to an exemplary embodiment, the early impulse response may be determined by early IR generator 204 for about the first 80 to 100 ms of the room impulse response. The late impulse response may be generated by late IR generator 206 for the remaining portion of the impulse response. The duration of the late impulse response generally depends on the reverberation time for the enclosure.

System 200 may optionally include display 216 configured to display at least one of early impulse responses h̅_{EARLY}, late impulse responses h̅_{LATE}, simulated room impulse responses h̅ or the predetermined enclosure parameters. It is contemplated that display 216 may include any display capable of presenting information including textual and/or graphical information.

System 200 may optionally include user interface 218, e.g., for use in selecting the enclosure parameters to simulate the room impulse response. User interface 218 may further be used to select enclosure parameters, impulse responses and other sound signals to be displayed and/or stored. User interface 218 may include a pointing device type interface for selecting control parameters using display 216. User interface 218 may further include a text interface for entering information, for example, a filename for storing the simulated room impulse response, such as in memory 210 or in a remote device (not shown).

System 200 may optionally include loudspeaker 214 for playing back the simulated room impulse responses. Loudspeaker 214 may include any loudspeaker capable of playing back the simulated room impulse responses.

System 200 may optionally include virtual room convolver 212 for convolving source sound signals X̅ with the simulated room impulse responses h̅, to form received signals Y̅. The sound signals may include any desired sound signal, such as anechoic sound signal (i.e. a sound signal having no enclosure shaping) which may be convolved with the simulated impulse responses h̅, as shown in eq. (1). The received signals Y̅, thus, may be played back, such as via loudspeaker 214, with the acoustical characteristics of the virtual room.

It is contemplated that system 200 may be configured to connect to a global information network, e.g. the Internet, (not shown) such that simulated room impulse response may also be transmitted to a remote location for further processing and/or storage.

A suitable controller 202, early IR generator 204, late IR generator 206, room impulse response generator 208, memory 210, virtual room convolver 212, loudspeaker 214, display 216 and user interface 218 for use with the present invention will be understood by one of skill in the art from the description herein.

Referring next to FIG. 4A, exemplary late IR generator 206 is shown. IR generator 206 includes coded sequence generator 402, spatial shaping generator 404, bandpass filter 406 and decay shape generator 408.

Coded sequence generator 402 generates a coded pseudorandom sequence, referred to as m̅. In general, coded sequence m̅ includes at least one pair of pseudorandom sequences. According to an exemplary embodiment, reciprocal pairs of random sequences may be generated based on maximum length sequences (MLS), as shown in equation 5:

m̅=[m(t),m_{R}(t)] (5)

where m(t) represents a MLS sequence and m_{R}(t) represents a reciprocal MLS-sequence. In general, any number of sources mᵥ(t)=m(t) m_{R}(t+v) may be used, where v is an integer greater than or equal to 1. Generation of a reciprocal MLS may be obtained from the time-reversed version m(t), such that m_{R}(t)=m (−t). Reciprocal pairs of MLS sequences may be easily generated, via time-reversal. In addition, the cross-correlation values of reciprocal MLS sequences are also sufficiently low, to allow for creation of a maximum desired perceived spaciousness.

Any suitable MLS-related sequence may be used, where the sequence possesses a pulse-like periodic autocorrelation function and where the periodic cross-correlation function between any pair of sequences selected from the set includes a peak values that is significantly lower than the peak value of the autocorrelation function. Other example sequences include, for example, Gold sequences and Kasami sequences. In this manner, a large number of sequences may be generated, from among which any pair possesses a low-valued cross-correlation. Examples of generating reciprocal MLS-related sequences may be found, for example, in Xiang et al., entitled “Simultaneous acoustic channel measurement via maximal-length-related sequences,” JASA vol. 117 no. 4, April 2005, pp. 1889-1894 and Xiang et al., entitled “Reciprocal maximum-length sequence pairs for acoustical dual source measurements,” JASA vol. 113 no. 5, May 2003, pp. 2754-2761, the contents of which are incorporated herein by reference.

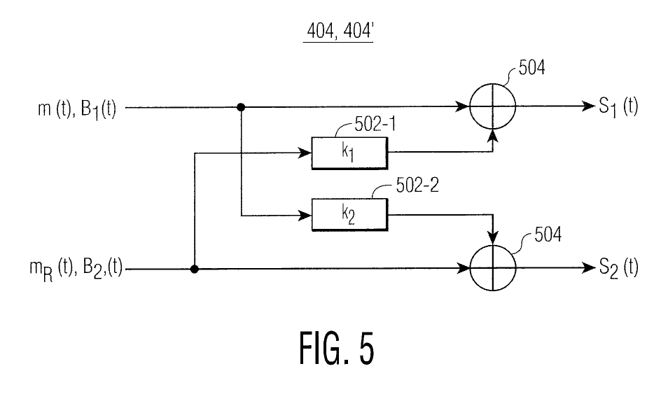

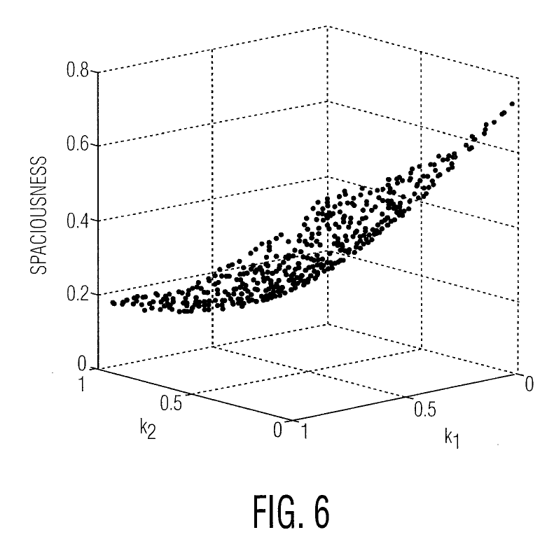

Spatial shaping block 404 receives coded sequence m̅ and generates a spatially shaped set of signals, S̅. In general, the coded sequence m̅ may be mixed by predetermined attenuation coefficients, described further below with respect to FIGS. 5 and 6, to provide a desired degree of spaciousness.

Referring to FIG. 5, spatial shaping generator 404 includes attenuation blocks 502-1, 502-2 for the respective channels and summer blocks 504. For a two channel system, the spatially shaped signals S̅ may be represented as:

S₁(t)=k₁m_{R}(t)+m(t)

S₂(t)=k₂m(t)+m_{R}(t) (6)

where S̅=[S₁(t), S₂(t)], k represents the attenuation coefficient for the respective channel and 0≦k≦1.

As shown in FIG. 5, coded sequence m(t) is multiplied by attenuation coefficient 502-2 (k₂) and coded sequence m_{R}(t) is multiplied by attenuation coefficient 502-1 (k₁), to form the signals shown in Eq. (6). Coded sequence m(t) is summed with the attenuated coded sequence m_{R}(t) to form spatially shaped signal S₁(t) via summer block 504. Coded sequence m_{R}(t) is summed with the attenuated coded sequence m(t) to form spatially shaped signal S₂(t) via summer block 504.

As shown in FIG. 6, each of attenuation coefficients k₁ and k₂ may be selected to match a spaciousness for one of a plurality of enclosures. In FIG. 6, spaciousness is related to IACC and the enclosures represent a plurality of concert halls having known spaciousness.

Referring back to FIG. 4A, bandpass filter block 406 receives the spatially shaped signals S̅ and applies a set of band pass filters over m frequency bands (for 1≦m≦M) to the spatially shaped signals S̅. Bandpass filter block 406 may band-pass filter the spatially shaped signals in octave bands or third octave bands, to form filtered signals B̅ₘ, for M number of frequency bands. According to an exemplary embodiment, frequency bands of between about 125 Hz to about 16 kHz may be used for bandpass filter block 406. A suitable bandpass filter block 406 may be understood from the description herein.

Decay shape generator 408 receives the filtered signals B̅ₘ, and applies an exponential decay to the filtered signals, for each frequency band m. The exponential decay may be represented by:

$$E ( t ) = {e}^{{α}_{band} ( t )} \\ where \\ {α}_{band} ( t ) = \frac{- 6.9 \cdot t}{{RT}_{band}} \qquad ( 7 )$$

and where RT_{band} represents the reverberation time for the enclosure for the respective octave or third octave band. The reverberation time represents an acoustic parameter that may be stored in memory 210 (FIG. 2), for example, as a predetermined enclosure parameter. Decay shape generator 408 multiplies the filtered signals B̅ₘ by the respective exponential decay in the corresponding frequency, to form the late impulse response h̅_{LATE} for each frequency band.

Referring to FIG. 4B, exemplary late IR generator 206′ is shown. Late IR generator 206′ includes coded sequence generator 402, bandpass filter 406, spatial shaping generator 404′ and decay shape generator 408. Late IR generator 206′ may optionally include IACC shaping applicator 410. Late IR generator 206, 206′ may also apply a fade-in ramp function to the late impulse response, prior to appending the late impulse response to the early impulse response. Any suitable fade-in ramp function may be applied to the beginning of the late impulse response. According to an exemplary embodiment, the ramp function may be between about 5 ms and about 10 ms in length.

Late IR generator 206′ is similar to late IR generator 404 (FIG. 4A), except that bandpass filter block 406 applies a set of band pass filters over m frequency bands to the coded sequence m̅, to form filtered signals B̅ₘ, for each frequency band m. In addition, spatial shaping generator 404′ receives the filtered signals B̅ₘ and generates a spatially shaped set of signals, S̅, for each frequency band m.

Spatial shaping generator 404′ applies a mixing matrix to the filtered signals, as described further below. For a two channel system, the spatially shaped signals S̅ may be represented as:

S₁^{m}(t)=k₁B₂^{m}(t)+B₁^{m}(t)

S₂^{m}(t)=k₂B₁^{m}(t)+B₂^{m}(t) (8)

where S̅ₘ=[S₁^{m}(t),S₂^{m}(t)], k represents the attenuation coefficient for the respective channel, m represents the frequency band and 0≦k≦1. In eq. (8), spatially shaped signals S̅ₘ are determined separately for each frequency band m.

Equation (8) may be rewritten in matrix form as:

$${[ \begin{matrix}{S}_{1} ( t ) \\ {S}_{2} ( t )\end{matrix} ]}_{m} = \overbrace{{[ \begin{matrix}1 & k \\ k & 1\end{matrix} ]}_{m}}^{mixing matrix} \cdot {[ \begin{matrix}{B}_{1} ( t ) \\ {B}_{2} ( t )\end{matrix} ]}_{m} \qquad ( 9 )$$

where the attenuation coefficients may be formulated as a mixing matrix. In eq. (9) the individual attenuation coefficient subscripts have been dropped.

Referring to FIG. 5, spatial shaping generator 404′ is similar to spatial shaping generator 404, except that spatial shaping generator 404′ applies filtered signals B₁(t) and B₂(t) to the attenuation coefficients 502 and summer blocks 504.

The mixing matrix may be selected to match a predetermined spatial index for a particular enclosure. The spatial index may be stored as one of the enclosure parameters in memory 210 (FIG. 2). As shown in eq. (9), a separate mixing matrix may be selected for each frequency band m.

For each frequency band m, the attenuation coefficients may be selected for each channel to control the amount of perceived spaciousness for the shaped response. In general, combining two channels together (i.e. combining B₁(t) and B₂(t)) tends to decrease a perceived spaciousness. Accordingly, if the attenuation coefficient k is set to 1, B₁(t) is maximally combined with B₂(t), and there is no perceived spaciousness for the channel. In contrast, if the attenuation coefficient k is set to 0, only one filtered signal (i.e., B₁(t) or B₂(t) depending on the channel in eq. (8)), and there is high perceived spaciousness for the channel.

In general, the spatial index for the reverberant tail relates to the late IACC, as described above. A spatial index may be determined for a number of predetermined enclosures, over a number of frequency bands m. The mixing matrix may be determined to substantially match the spatial index, for each of the predetermined enclosures.

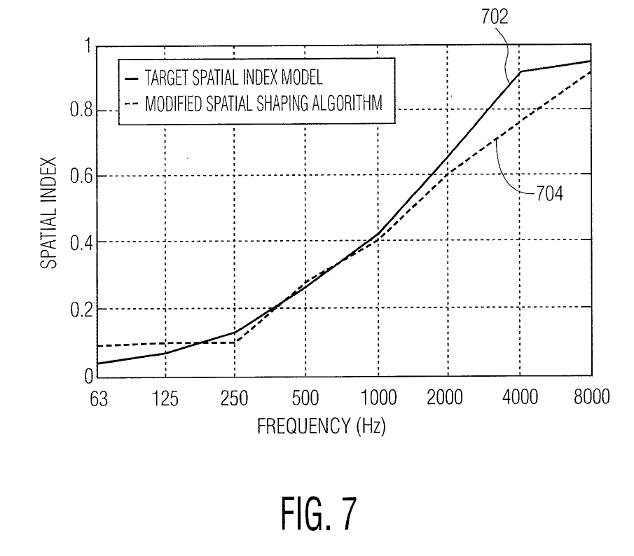

Referring to FIG. 7, an example graph is shown of spatial index 702 for a predetermined concert hall as a function of frequency. In addition, spatial index 704 is shown for a late impulse response simulated according to eq. (9) is shown. As can be seen in FIG. 7, late IR generator 206′ (FIG. 4B) may generate spatially enveloping reverberation which corresponds with an actual enclosure.

Although FIG. 5 illustrates an example of a two channel spatial shaping generator 404′, spatial shaping generator 404′ may be applied to multiple channels. According to another embodiment, spatial shaping generator 404′ may apply spatial shaping to any multiple number of channels L to provide an LxL-sized mixing matrix. For example, a four channel mixing matrix may be represented as:

$${[ \begin{matrix}{S}_{1} ( t ) \\ {S}_{2} ( t ) \\ {S}_{3} ( t ) \\ {S}_{4} ( t )\end{matrix} ]}_{m} = {[ \begin{matrix}1 & k & k & k \\ k & 1 & k & k \\ k & k & 1 & k \\ k & k & k & 1\end{matrix} ]}_{m} \cdot {[ \begin{matrix}{B}_{1} ( t ) \\ {B}_{2} ( t ) \\ {B}_{3} ( t ) \\ {B}_{4} ( t )\end{matrix} ]}_{m} \qquad ( 10 )$$

The mixing matrix may be selected to substantially match a spatial index for a predetermined enclosure, as described above.

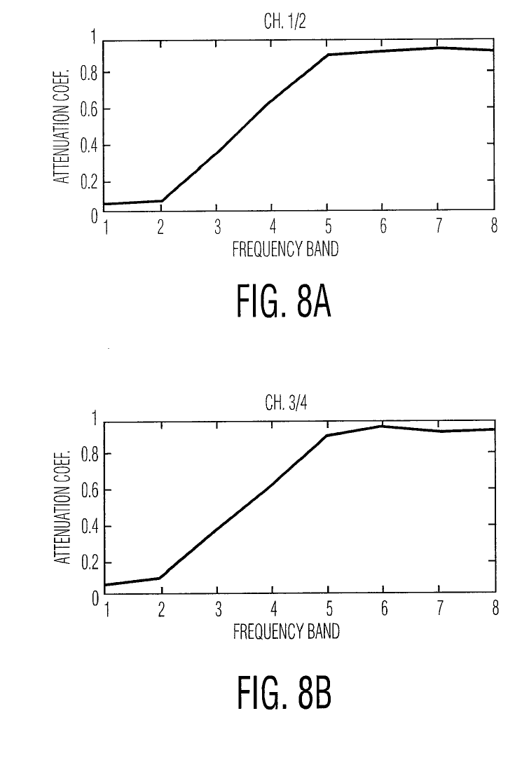

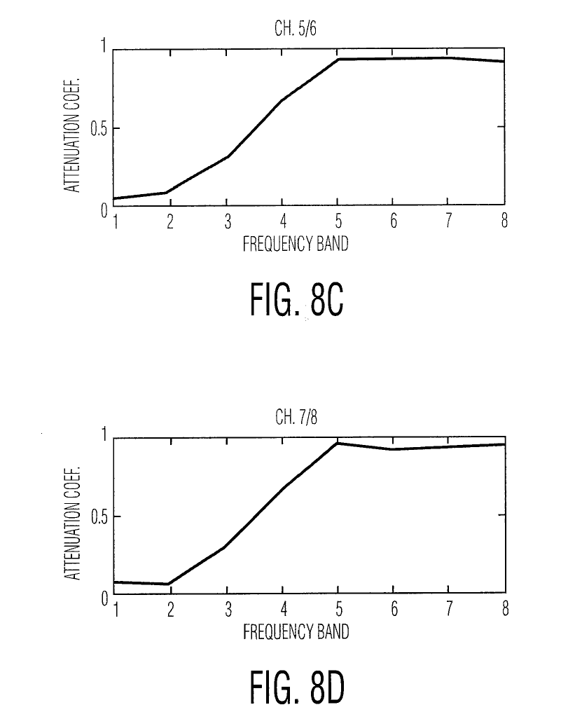

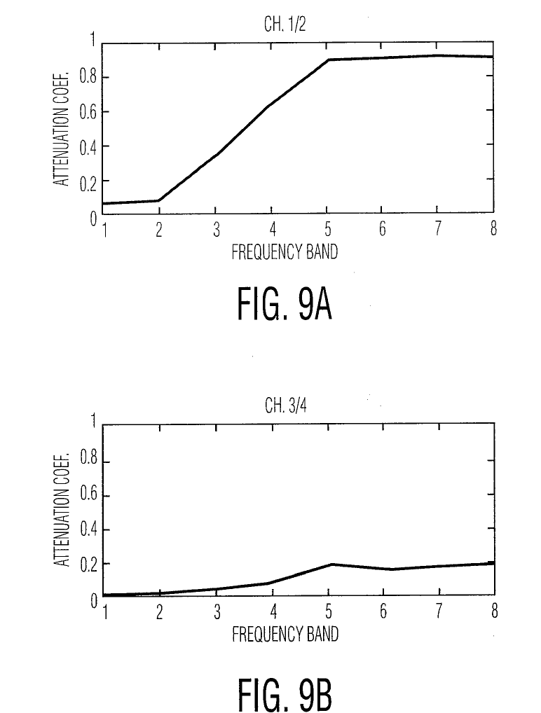

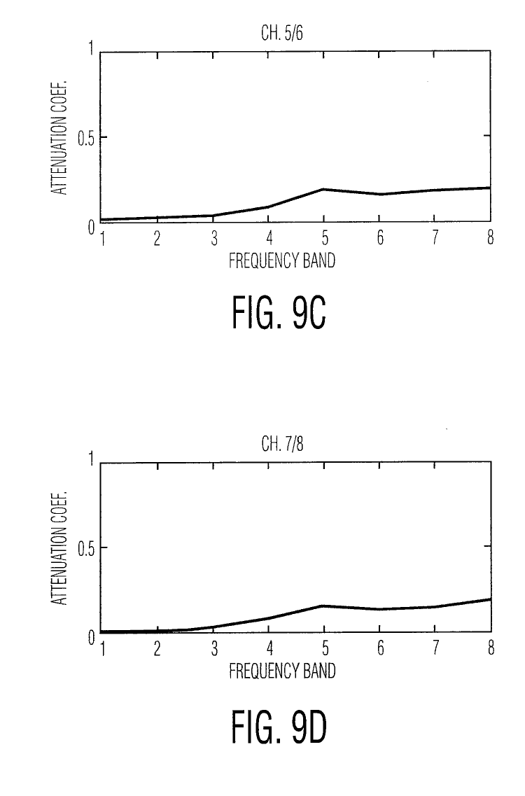

Referring to FIGS. 8A-8D and 9A-9D, examples of mixing matrix selection are shown for spatial index control. In FIGS. 8A-8D and 9A-9D, the spatial index is shown as a function of frequency band for an exemplary late IR generator 206′ (FIG. 4B) configured for eight channels. In FIGS. 8A-8D and 9A-9D, the x-axis relates to octave band numbers for the octave bands between 63 Hz and 8 kHz.

In FIGS. 8A-8D, each of the channels are selected to have a lower spatial index for the first and second frequency bands, an increasing spatial index from the second frequency band through the fifth frequency band, and a high spatial index for the remaining frequency bands. In FIGS. 9A-9D, each channel is selected to have a different spatial index for each frequency band.

Referring back to FIG. 4B, late IR generator 206′ may also include IACC shaping applicator 410. IACC shaping applicator 410 may receive the late impulse response, for each frequency band, and apply a further spatial shaping, φ, to the late impulse response, based on the IACC. For example, for two channels in frequency band m, the further spatial shaping may be represented as:

$${h}_{1}^{′} ( t ) = cos φ \cdot {h}_{1} ( t ) + sin φ \cdot {h}_{2} ( t ) \\ {h}_{2}^{′} ( t ) = sin φ \cdot {h}_{1} ( t ) + cos φ \cdot {h}_{2} ( t ) \\ where \\ φ = \frac{1}{2} arcsin ( IACC ) . \qquad ( 11 )$$

Equation (11) may also be represented in matrix form as:

$${[ \begin{matrix}{h}_{1}^{′} ( t ) \\ {h}_{2}^{′} ( t )\end{matrix} ]}_{m} = {[ \begin{matrix}cos φ & sin φ \\ sin φ & cos φ\end{matrix} ]}_{m} \cdot {[ \begin{matrix}{h}_{1} ( t ) \\ {h}_{2} ( t )\end{matrix} ]}_{m} \qquad ( 12 )$$

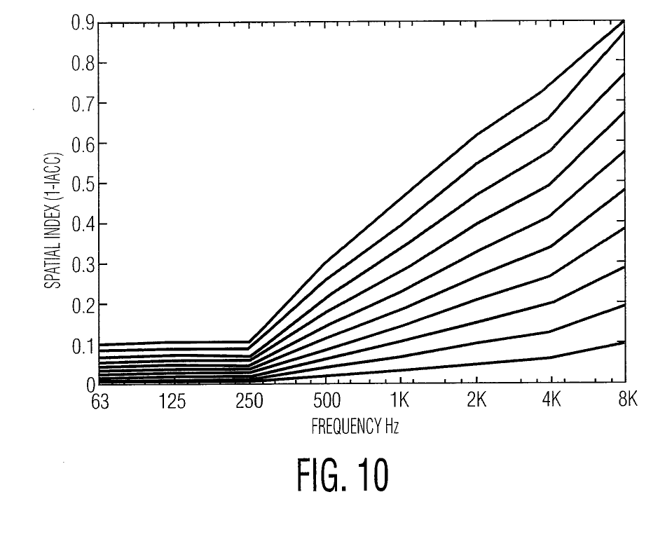

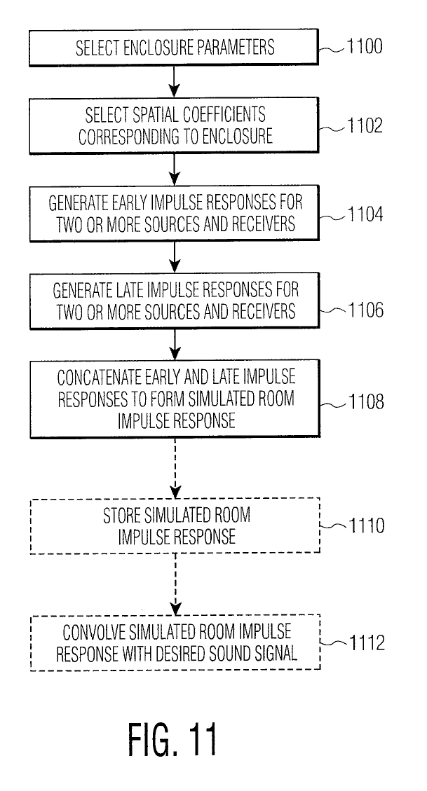

The IACC may be stored in memory 210 (FIG. 2) for a number of enclosures. FIG. 10 is a graph of the IACC as a function of frequency for a plurality of different enclosures.

According to an exemplary embodiment of the present invention, equation (12) may also be expanded for multiple channels as:

$${[ \begin{matrix}{h}_{1}^{′} ( t ) \\ {h}_{2}^{′} ( t ) \\ {h}_{3}^{′} ( t ) \\ {h}_{4}^{′} ( t )\end{matrix} ]}_{m} = {[ \begin{matrix}cos φ & k sin φ & k sin φ & k sin φ \\ k sin φ & cos φ & k sin φ & k sin φ \\ k sin φ & k sin φ & cos φ & k sin φ \\ k sin φ & k sin φ & k sin φ & cos φ\end{matrix} ]}_{m} \cdot {[ \begin{matrix}{h}_{1} ( t ) \\ {h}_{2} ( t ) \\ {h}_{3} ( t ) \\ {h}_{4} ( t )\end{matrix} ]}_{m} \qquad ( 13 )$$

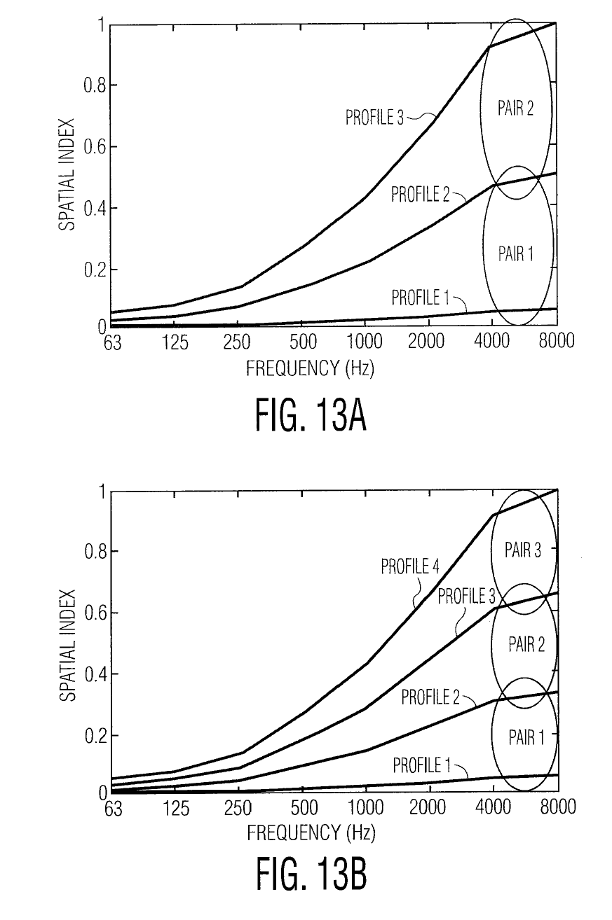

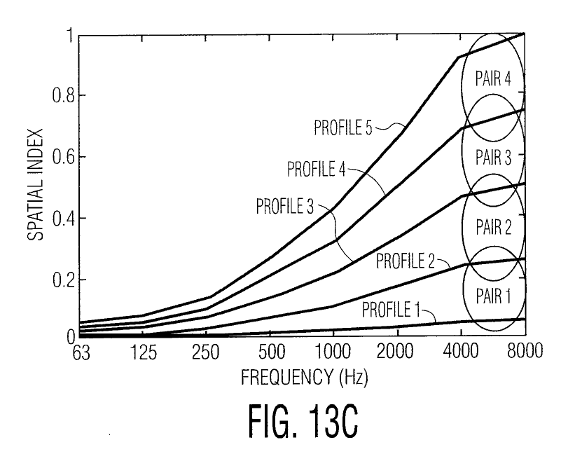

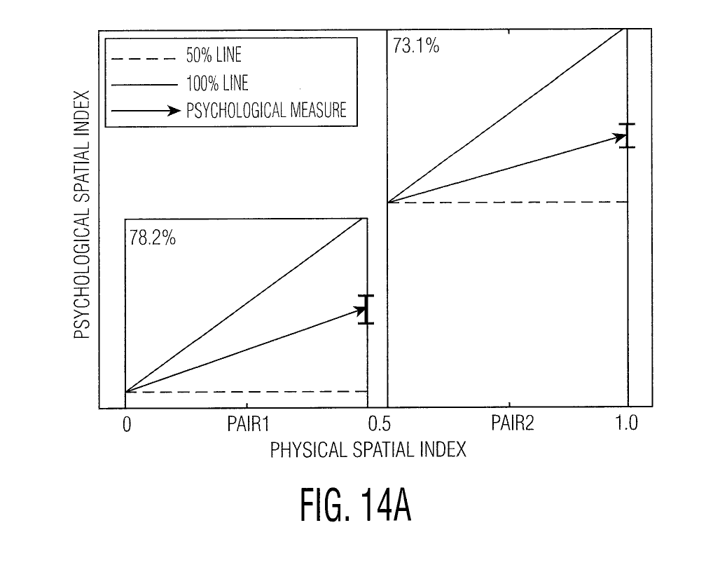

By using eqs. (11-13), the summed broadband late-impulse response may be further controlled for a desired overall spatial index profile. For example, referring to FIG. 13A, the basic spatial index profiles may be the same, with a different applied overall shaping. Accordingly, a different degree of spatial index may be produced, for a different degree of spaciousness.

Referring to FIG. 11, an exemplary method for generating simulated room impulse responses is shown. At step 1100, enclosure parameters are selected. For example, a user may select enclosure parameters for a predetermined enclosure via user interface 218 (FIG. 2). The enclosure parameters may include predetermined enclosure dimensions, acoustic properties and/or psychoacoustic properties. Alternately, enclosure parameters such as dimensions, acoustic properties and/or psychoacoustic properties may be entered to generate a new virtual enclosure. The new enclosure may also be stored, for example, in memory 210 (FIG. 2).

At step 1102, spatial coefficients corresponding to the predetermined enclosure are selected. The spatial coefficients may include spatial coefficients to be applied to the early impulse response and attenuation coefficients to be applied to the late impulse response. For example, controller 202 (FIG. 2), may select the spatial coefficients from memory 210 responsive to the selected enclosure parameters in step 1100.

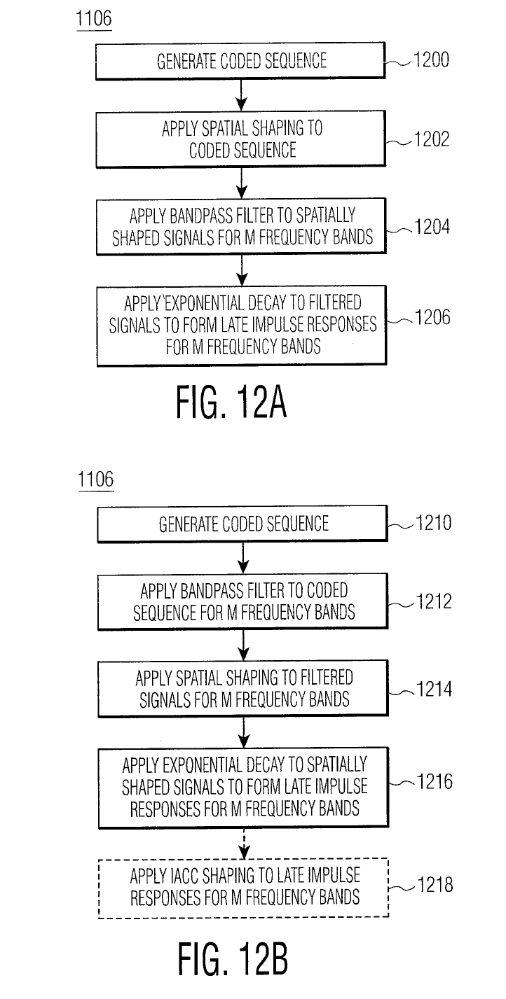

At step 1104, early impulse responses are generated for two or more sources and receivers, for example, by early IR generator 204 (FIG. 2). At step 1106, late impulse responses are generated for two or more sources and receivers, for example, by late IR generator 206 (FIG. 2). Step 1106 is further described with respect to FIGS. 12A and 12 B. At step 1108, the early and late impulse responses are concatenated to form a simulated room impulse response, for example by room impulse response generator 208 (FIG. 2). As described above, before concatenation, the late impulse responses may be faded into with an applied slow-ramp function at the beginning of the late impulse response.

At optional step 1110, the simulated room impulse response may be stored, for example, by memory 210 (FIG. 2). At optional step 1112, the simulated room impulse response may be convolved with a desired sound signal, for example, by virtual room convolver 212 (FIG. 2).

Referring to FIG. 12A an exemplary method for generating late impulse responses, step 1106, is shown. At step 1200, a coded pseudorandom sequence is generated, for example, by coded sequence generator 402 (FIG. 4A). At step 1202, spatial shaping is applied to the coded sequence, for example, by spatial shaping generator 404 (FIG. 4A).

At step 1204, the spatially shaped signals are band-pass filtered over a plurality of frequency bands, for example, by bandpass filter 406 (FIG. 4A). At step 1206, an exponential decay is applied to the filtered signals, for each frequency band, to form late impulse responses, for example, by decay shape generator 408 (FIG. 4A).

Referring to FIG. 12B an exemplary method for generating late impulse responses, step 1106, is shown, according to another embodiment. At step 1210, a coded pseudorandom sequence is generated, for example, by coded sequence generator 402 (FIG. 4B). At step 1212, the coded sequences are band-pass filtered over a plurality of frequency bands, for example, by bandpass filter 406 (FIG. 4B).

At step 1214, spatial shaping is applied to the filtered signals, over each frequency band, for example, by spatial shaping generator 404′ (FIG. 4B). At step 1216, an exponential decay is applied to the spatially shaped signals, for each frequency band, to form late impulse responses, for example, by decay shape generator 408 (FIG. 4B).

At optional step 1218, an IACC shaping is applied to the late impulse responses, for each frequency band, for example, by IACC shaping applicator 410 (FIG. 4B).

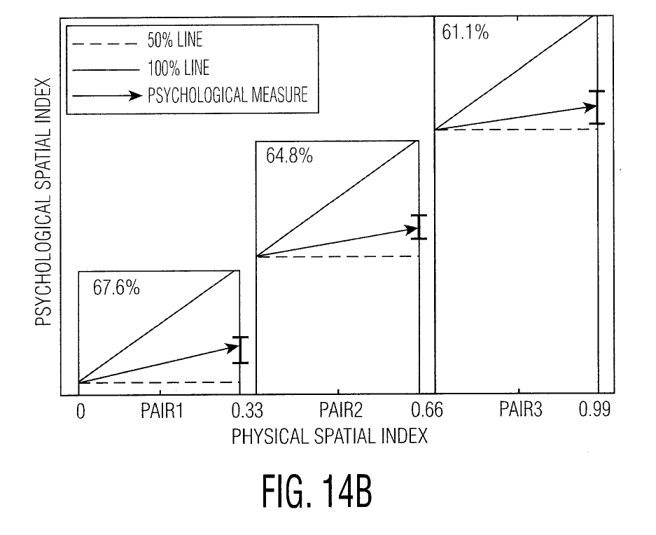

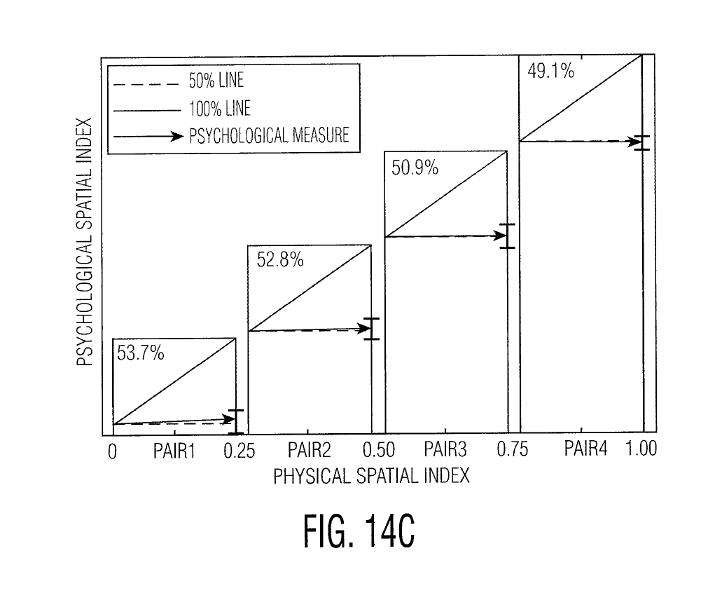

Referring next to FIGS. 13A-14C and 14A-14C, example results of subjective testing of exemplary simulated impulse responses are provided. In particular, FIGS. 13A-13C are graphs of spatial index as a function of frequency for several example profiles used to test simulated impulse responses; and FIGS. 14A-14C are graphs of a psychological spatial index as a function of physical spatial index illustrating the test results for the profiles shown in respective FIGS. 13A-13C. Additional testing is described further below. For each of the subjective tests, a total number of 18 subjects were used and all tests were reproduced binaurally.

FIGS. 13A-13C and 14A-14C relate to tests associated with the ability of subjects to perceive changes in spaciousness. Three spatial groups were generated, corresponding to respective FIGS. 13A-13C. Pairs were generated within each spatial group for a total of nine pairs. Pairs and their reversed pairs were presented twice, yielding a total of 36 pairs. For spatial variations, spatial index profiles were presented for comparison from only a single pair. Early sound profiles were categorized, based on CATT-Acoustic™, as being small (with a 0.95 second reverberation time), medium (1.4 second reverberation time) or large (2 second reverberation time).

The test results are shown in FIGS. 14A-14C and indicate a physical spatial index, a perceived spatial index, as well as the relationship between these two indices. The test results clearly indicate that well-controlled different degrees of perceived spaciousness can be achieved.

A second test included comparing spatially shaped and spatially unshaped spatial profiles in the late room impulse response. By spatially unshaped, the spatial index over each frequency band is substantially the same, without including a shape of the naturally measured room characteristics. The second test provides a comparison for sources directed to a side of a binaural receiver (i.e., such that there is a delay in the received sound to each ear) and for sources directly in front of a binaural receiver (i.e., so that each ear receives the sound at the same time). For sources directly in front of the binaural receiver, 55.56 percent of the subjects (18 total subjects) selected the spatially shaped profile, 22.22 percent of the subjects selected the unshaped profile and 22.22 percent did not perceive a difference. For sources located to the side of the binaural receiver, 72.22 percent of the subjects (18 total subjects) selected the spatially shaped profile, 16.67 percent of the subjects selected the unshaped profile and 11.11 percent did not perceive a difference. These test results clearly indicate that including spatial shaping according to embodiments of the present invention is a better approach as compared with conventional reverberation tail simulators.

A third test compared measured and simulated room impulse responses which were spatially shaped according to embodiments of the present invention. 44.44 percent of the subjects (18 total subjects) selected the measured shaped profile, 33.33 percent of the subjects selected the unshaped profile and 22.22 percent did not perceive a difference, indicating that reverberation tails simulated with an exemplary spatial shaping generator according to the present invention produces a similar perceived listening experience as compared to measured room impulse responses.

Although the invention has been described in terms of systems and methods for generating simulated room impulse responses including spatially enveloping reverberation, it is contemplated that one or more components may be implemented in software on microprocessors/general purpose computers (not shown). In this embodiment, one or more of the functions of the various components may be implemented in software that controls a general purpose computer. This software may be embodied in a computer readable medium, for example, a magnetic or optical disk, or a memory-card.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A method for simulating at least one room impulse response between two or more sound sources and two or more receivers positioned in an enclosure, the method comprising:
generating at least one early impulse response including early reflections from the two or more sound sources to at least one of the receivers;
generating at least one late impulse response including a reverberation portion, the late impulse response generated to spatially shape the reverberation portion corresponding to a spatial parameter of the enclosure; and
combining the at least one early impulse response with the at least one late impulse response to form the at least one simulated room impulse response.

2. The method according to claim 1, further comprising, prior to generating the at least one early impulse response, selecting at least one enclosure parameter for the enclosure,
wherein the spatial parameter is selected responsive to the enclosure parameter.

3. The method according to claim 2, wherein the enclosure parameter includes at least one of a predetermined enclosure, an enclosure dimension, an acoustical property of the enclosure or a psychoacoustic property of the enclosure.

4. The method according to claim 1, further including convolving the at least one simulated room impulse response with a predetermined sound signal.

5. The method according to claim 1, further comprising applying a spatial shaping to the at least one late impulse response according to a predetermined interaural cross correlation coefficient (IACC) corresponding to the enclosure.

6. A tangible computer readable medium including computer program instructions configured to cause a computer to perform the method of claim 1.

7. The method according to claim 1, wherein generating the at least one late impulse response includes:
generating a set of pseudorandom sequences corresponding to the number of sound sources;
applying a spatial shaping to the set of pseudorandom sequences based on the spatial parameter to form spatially shaped signals; and
applying an exponential decay to the spatially shaped signals corresponding to a reverberation time of the enclosure.

8. The method according to claim 7, wherein the pseudorandom sequence includes at least one of a maximum length sequence (MLS), a reciprocal MLS, a Gold sequence or a Kasami sequence.

9. The method according to claim 7, further comprising, prior to applying the spatial shaping, band-pass filtering the set of pseudorandom sequences over a plurality of frequency bands,
wherein the spatial parameter includes a spatial parameter corresponding to each of the frequency bands and the spatial shaping is applied to the filtered sequences in each frequency band using the corresponding spatial parameter.

10. The method according to claim 9, wherein the reverberation time includes a reverberation time corresponding to each of the frequency bands and the exponential decay is applied to the spatially shaped signals in each frequency band using the corresponding reverberation time.

11. The method according to claim 7, further comprising, after applying the spatial shaping, band-pass filtering the spatially shaped signals over a plurality of frequency bands,
wherein the reverberation time includes a reverberation time corresponding to each of the frequency bands and the exponential decay is applied to the filtered signals in each frequency band using the corresponding reverberation time.

12. The method according to claim 7, wherein applying the spatial shaping to the set of pseudorandom sequences includes multiplying the set of pseudorandom sequences with a mixing matrix, the mixing matrix spatially shaping the pseudorandom sequences according to the spatial parameter.

13. The method according to claim 12, wherein the mixing matrix is selected to substantially match the spatial parameter.

14. A system for simulating at least one room impulse response between two or more sound sources and two or more receivers positioned in an enclosure, the system comprising:
an early impulse response (IR) generator configured to generate at least one early impulse response including early reflections from the two or more sound sources to at least one of the receivers;
a late IR generator configured to generate at least one late impulse response including a reverberation portion, the late impulse IR generator spatially shaping the reverberation portion corresponding to a spatial parameter of the enclosure; and
a room impulse response generator configured to combine the at least one early impulse response with the at least one late impulse response to form the at least one simulated room impulse response.

15. The system according to claim 14, further comprising:
a controller configured to receive an enclosure parameter for the enclosure and to select the spatial parameter responsive to the enclosure parameter.

16. The system according to 15, wherein the enclosure parameter includes at least one of a predetermined enclosure, an enclosure dimension, an acoustical property of the enclosure or a psychoacoustic property of the enclosure.

17. The system according to claim 15, further comprising:
a user interface configured to select the enclosure parameter for the enclosure.

18. The system according to claim 14, further comprising:
a virtual room convolver configured to convolve the at least one simulated room impulse response with a predetermined sound signal.

19. The system according to claim 14, wherein the late IR generator includes:
a coded sequence generator configured to generate a set of pseudorandom sequences corresponding to the number of sound sources;
a spatial shaping generator configured to apply a spatial shaping to the set of pseudorandom sequences based on the spatial parameter, to form spatially shaped signals; and
a decay shape generator configured to apply an exponential decay to the spatially shaped signals corresponding to a reverberation time of the enclosure.

20. The system according to claim 19, wherein the late IR generator further includes:
a bandpass filter configured to band-pass filter one of the set of pseudorandom sequences received from the coded sequence generator and the spatially shaped signals received from the spatial shaping generator over a plurality of frequency bands.

21. The system according to claim 19, wherein the spatial shaping generator applies the spatial shaping to substantially match the spatial parameter.

22. The system according to claim 14, further comprising an interaural cross correlation coefficient (IACC) shaping applicator configured to apply a spatial shaping to the at least one late impulse response according to a predetermined IACC corresponding to the enclosure.
